(19) United States
(12) Patent Application Publication
(10) Pub. No.: US 2024/0321700 A1
(43) Pub. Date: Sep. 26, 2024

(54) SEMICONDUCTOR PACKAGE AND SEMICONDUCTOR PACKAGE MANUFACTURING METHOD

(71) Applicant: Samsung Electronics Co., Ltd., Suwon-si (KR)

(72) Inventors: Daeyeun Choi, Suwon-si (KR); Taeho Ko, Suwon-si (KR); Unbyoung Kang, Suwon-si (KR); Seokbong Park, Suwon-si (KR)

(21) Appl. No.: 18/612,492

(22) Filed: Mar. 21, 2024

(30) Foreign Application Priority Data
Mar. 24, 2023 (KR) 10-2023-0038964
May 2, 2023 (KR) 10-2023-0057368

(51) Int. Cl. H01L 23/498; H01L 21/52; H01L 21/56; H01L 23/00; H01L 23/31; H01L 25/10; H10B 80/00

(52) U.S. Cl. CPC H01L 23/49811; H01L 21/52; H01L 21/56; H01L 23/3107; H01L 24/16; H01L 24/19; H01L 24/20; H01L 24/81; H01L 25/105; H10B 80/00; H01L 2224/16227; H01L 2224/19; H01L 2224/2101; H01L 2224/22; H01L 2224/81

(57) ABSTRACT

A semiconductor package includes an upper redistribution structure, a first substrate, a first semiconductor chip, a second semiconductor chip, a bridge chip, and a first insulating layer. The upper redistribution structure includes an upper redistribution insulating layer and upper redistribution patterns. The first substrate includes an upper surface, a lower surface, a first cavity extending in a vertical direction, and a second cavity provided apart from the first cavity in a horizontal direction and extending in the vertical direction. The first substrate is on an upper surface of the upper redistribution structure. The first semiconductor chip is accommodated in the first cavity and electrically connected to a subset of the upper redistribution patterns. The second semiconductor chip is accommodated in the second cavity and electrically connected to a subset of the upper redistribution patterns. The bridge chip is below the upper redistribution structure. The first insulating layer surrounds the bridge chip.

### CROSS-REFERENCE TO RELATED APPLICATION

This application is based on and claims priority under 35 U.S.C. § 119 to Korean Patent Application No. 10-2023-0038964, filed on Mar. 24, 2023, in the Korean Intellectual Property Office, and Korean Patent Application No. 10-2023-0057368, filed on May 2, 2023, in the Korean Intellectual Property Office, the disclosures of which are incorporated by reference herein in their entireties.

### BACKGROUND

The disclosure relates to a semiconductor package and a semiconductor package manufacturing method, and more particularly, to a semiconductor package having improved reliability and a method of manufacturing the semiconductor package.

Recently, in the electronic product market, demand for portable devices has rapidly increased, and as a result, small and light-weight electronic components are required for such electronic products. To reduce the size and weight of electronic components, semiconductor packages included in electronic components are required to have a small volume and high data processing capacity.

### SUMMARY

The disclosure provides a semiconductor package configured to reduce residue during the formation of conductive pillars, improve compatibility between first and second semiconductor chips and redistribution structures, and prevent warpage by minimally forming a molding member, and a method of manufacturing the semiconductor package.

The benefits and technical benefits of embodiments according to this disclosure are not limited to those mentioned above, and the disclosure will be apparently understood by those skilled in the art through the following description.

According to an aspect of the disclosure, there is provided a semiconductor package.

The semiconductor package includes an upper redistribution structure, a first substrate, a first semiconductor chip, a second semiconductor chip, a bridge chip, and a first insulating layer. The upper redistribution structure includes an upper redistribution insulating layer and upper redistribution patterns in the upper redistribution insulating layer. The first substrate includes an upper surface, a lower surface opposite the upper surface, a first cavity extending in a vertical direction from the upper surface to the lower surface, and a second cavity provided apart from the first cavity in a horizontal direction and extending in the vertical direction from the upper surface to the lower surface. The first substrate is on an upper surface of the upper redistribution structure. The first semiconductor chip is accommodated in the first cavity and is electrically connected to a first subset of the upper redistribution patterns. The second semiconductor chip is accommodated in the second cavity and is electrically connected to a second subset of the upper redistribution patterns. The bridge chip is below the upper redistribution structure. The first insulating layer surrounds the bridge chip.

According to another aspect of the disclosure, there is provided a semiconductor package manufacturing method.

The semiconductor package manufacturing method includes providing a first substrate having a first cavity and a second cavity, mounting a first semiconductor chip in the first cavity and a second semiconductor chip in the second cavity, forming an upper redistribution structure including upper redistribution patterns electrically connected to each of the first semiconductor chip and the second semiconductor chip, mounting a bridge chip such that the bridge chip is electrically connected to the upper redistribution structure, forming a first insulating layer surrounding the bridge chip, forming a conductive pillar penetrating the first insulating layer, and forming a lower redistribution structure including a lower redistribution pattern electrically connected to the conductive pillar.

According to another aspect of the disclosure, there is provided a semiconductor package.

The semiconductor package includes an upper redistribution structure, a first substrate, a first semiconductor chip, a second semiconductor chip, a film, a bridge chip, a first insulating layer, a conductive pillar, and a lower redistribution structure. The upper redistribution structure includes an upper redistribution insulating layer and upper redistribution patterns in the upper redistribution insulating layer. The first substrate includes an upper surface, a lower surface opposite the upper surface, a first cavity extending in a vertical direction from the upper surface to the lower surface, and a second cavity provided apart from the first cavity in a horizontal direction and extending in the vertical direction from the upper surface to the lower surface. The first substrate is on an upper surface of the upper redistribution structure. The first semiconductor chip is accommodated in the first cavity and is electrically connected to a first subset of the upper redistribution patterns. The second semiconductor chip is accommodated in the second cavity and is electrically connected to a second subset of the upper redistribution patterns. The film fills a gap between the first substrate and the first semiconductor chip and a gap between the first substrate and the second semiconductor chip. The bridge chip is below the upper redistribution structure. The first insulating layer surrounds the bridge chip. The conductive pillar penetrates the first insulating layer in the vertical direction. The lower redistribution structure is provided below the first insulating layer and includes a lower redistribution pattern electrically connected to the conductive pillar. The upper redistribution patterns include an upper redistribution line pattern and an upper redistribution via pattern that has a horizontal width increasing in the vertical direction away from the first substrate. The conductive pillar has a horizontal width decreasing in the vertical direction away from the upper redistribution structure. The first insulating layer includes a dielectric film.

### BRIEF DESCRIPTION OF THE DRAWINGS

Embodiments will be more clearly understood from the following detailed description taken in conjunction with the accompanying drawings in which:

FIG. 1 is a cross-sectional view schematically illustrating an example of a semiconductor package according to some embodiments;

FIG. 2 is a cross-sectional view schematically illustrating an example of a first semiconductor chip according to some embodiments;

FIG. 3 is a flowchart schematically illustrating an example semiconductor package manufacturing method according to some embodiments; and

FIGS. 4A to 4M are cross-sectional views illustrating an example of a semiconductor package manufacturing method according to some embodiments.

### DETAILED DESCRIPTION OF THE EMBODIMENTS

Hereinafter, embodiments will be described with reference to the accompanying drawings. In the drawings, like reference numerals denote like elements, and repeated descriptions thereof are omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

As used herein, the singular forms “a”, “an” and “the” are intended to include the plural forms as well, unless the context clearly indicates otherwise. When an element is said to be electrically connected to a plurality of elements, it will be understood that the element may be electrically connected to a subset of the plurality of elements, which subset of elements may be electrically insulated from one another and/or the remainder of the plurality of elements. As used herein, the term “and/or” includes any and all combinations of one or more of the associated listed items and may be abbreviated as “/”.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

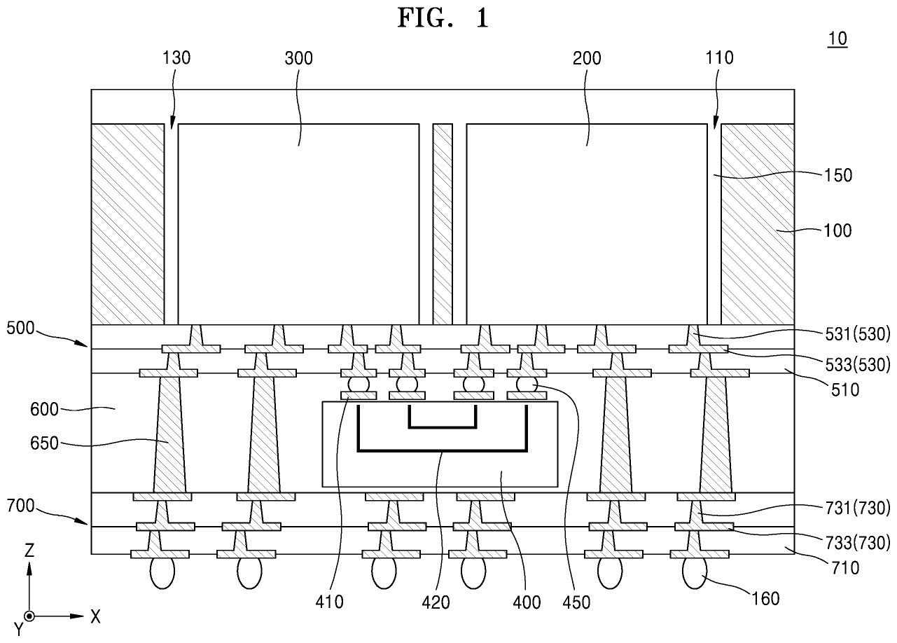

FIG. 1 is a cross-sectional view schematically illustrating a semiconductor package 10 according to some embodiments.

Referring to FIG. 1, the semiconductor package 10 may include a first substrate 100, a first semiconductor chip 200, a second semiconductor chip 300, a film 150, an upper redistribution structure 500, a first insulating layer 600, a bridge chip 400, conductive pillars 650, and a lower redistribution structure 700.

The first substrate 100 may have an upper surface and a lower surface opposite the upper surface and may be positioned above the upper redistribution structure 500. In this case, the lower surface of the first substrate 100 may face the upper redistribution structure 500, and the upper surface of the upper redistribution structure 500 may face the first substrate 100. The lower surface of the first substrate 100 may be in contact with the upper surface of the upper redistribution structure 500.

In the following descriptions of the drawings, an X-axis direction and a Y-axis direction may refer to directions that are parallel to the upper or lower surface of the first substrate 100 and are perpendicular to each other. A Z-axis direction may refer to a direction perpendicular to the upper or lower surface of the first substrate 100. For example, the Z-axis direction may be perpendicular to an X-Y plane.

Furthermore, in the following descriptions of the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first substrate 100 may include a first cavity 110 and a second cavity 130. A cavity may be a hole or recess in an element which may be unfilled or filled with another material and/or elements. The first cavity 110 may extend in the vertical direction (Z-axis direction) from the upper surface of the first substrate 100 to the lower surface of the first substrate 100. For example, the first cavity 110 may be a hole penetrating the first substrate 100 in the vertical direction (Z-axis direction). In some embodiments, the first cavity 110 may penetrate completely through the first substrate 100 from the upper surface to the lower surface. The second cavity 130 may be spaced apart from the first cavity 110 in a horizontal direction and may extend in the vertical direction (Z-axis direction) from the upper surface of the first substrate 100 to the lower surface of the first substrate 100 (e.g., completely through the first substrate 100).

The first semiconductor chip 200 may be accommodated in the first cavity 110 of the first substrate 100 (e.g., located within the first cavity 110). As the first semiconductor chip 200 is accommodated in the first cavity 110, the first substrate 100 may surround lateral surfaces of the first semiconductor chip 200.

The second semiconductor chip 300 may be accommodated in the second cavity 130 of the first substrate 100 (e.g., located within the second cavity 130). As the second semiconductor chip 300 is accommodated in the second cavity 130, the first substrate 100 may surround lateral surfaces of the second semiconductor chip 300.

In some embodiments, the first substrate 100 may be formed of and/or include, for example, a ceramic substrate, a printed circuit board (PCB), an organic substrate, or the like. In some embodiments, the first substrate 100 may not include a wiring layer therein. For example, the first substrate 100 may not be electrically connected to the upper redistribution structure 500. The first substrate 100 may serve as a mold surrounding both the first semiconductor chip 200 and the second semiconductor chip 300.

Each of the first semiconductor chip 200 and the second semiconductor chip 300 may be disposed on the upper redistribution structure 500. The lower surface of each of the first semiconductor chip 200 and the second semiconductor chip 300 may be in contact with the upper surface of the upper redistribution structure 500. Each of the first semiconductor chip 200 and the second semiconductor chip 300 may be electrically connected to upper redistribution patterns 530 of the upper redistribution structure 500. Each upper redistribution pattern 530 of the upper redistribution patterns 530 may be electrically insulated from another upper redistribution pattern 530 of the upper redistribution patterns 530. Each of the first semiconductor chip 200 and the second semiconductor chip 300 may be electrically connected to a respective subset of the upper redistribution patterns 530 of the upper redistribution structure 500. The respective subsets of the upper redistribution patterns 530 may have overlapping members (e.g., a first upper redistribution pattern 530 may be a member of a first subset electrically connected to the first semiconductor chip 200 and a member of a second subset electrically connected to the second semiconductor chip 300). Each of the first semiconductor chip 200 and the second semiconductor chip 300 may be electrically connected to the bridge chip 400 and the conductive pillars 650 through the upper redistribution patterns 530.

Each of the first semiconductor chip 200 and the second semiconductor chip 300 may be a memory chip or a logic chip. For example, the memory chip may be a volatile memory chip such as dynamic random access memory (DRAM) or static random access memory (SRAM), or may be a nonvolatile memory chip such as phase-change random access memory (PRAM), magnetoresistive random access memory (MRAM), ferroelectric random access memory (FeRAM), or resistive random access memory (RRAM). For example, the logic chip may be a microprocessor such as a central processing unit (CPU), a graphics processing unit (GPU), or an application processor (AP), an analog device, or a digital signal processor.

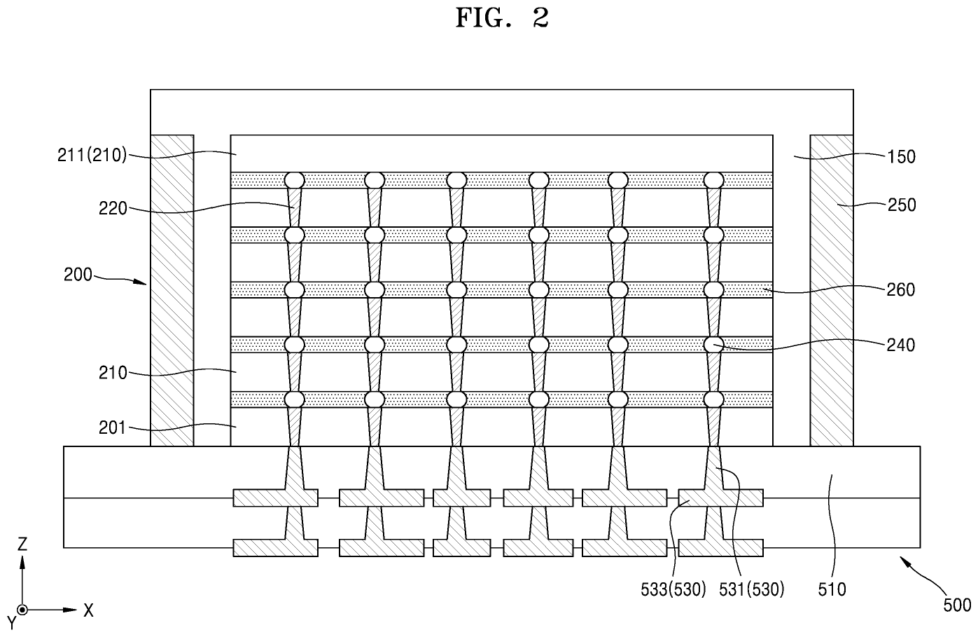

According to embodiments, the first semiconductor chip 200 and the second semiconductor chip 300 may be of different types. For example, the first semiconductor chip 200 may be a memory chip and the second semiconductor chip 300 may be a logic chip, or conversely, the first semiconductor chip 200 may be a logic chip and the second semiconductor chip 300 may be a memory chip. The following description will be given based on an embodiment in which the first semiconductor chip 200 includes a memory chip and the second semiconductor chip 300 includes a logic chip. In some embodiments, the first semiconductor chip 200 may include a chip stack structure in which a plurality of high bandwidth memory (HBM) chips are stacked in the vertical direction. This is described with reference to FIG. 2.

The film 150 may fill a gap between the first semiconductor chip 200 and the first substrate 100 and a gap between the second semiconductor chip 300 and the first substrate 100. For example, when an empty space is formed between the first semiconductor chip 200 and the first substrate 100 as the first semiconductor chip 200 is mounted in the first cavity 110, the film 150 may be formed in the empty space to fix the first semiconductor chip 200 and the first substrate 100 to each other. Similarly, when an empty space is formed between the second semiconductor chip 300 and the first substrate 100 as the second semiconductor chip 300 is mounted in the second cavity 130, the film 150 may be formed in the empty space to fix the second semiconductor chip 300 and the first substrate 100 to each other.

In some embodiments, the film 150 may cover upper surfaces of the first semiconductor chip 200 and the second semiconductor chip 300. In this case, the film 150 may cover the upper surface of the first substrate 100 together with the upper surfaces of the first semiconductor chip 200 and the second semiconductor chip 300.

The upper redistribution structure 500 may be under the first substrate 100. According to some embodiments, the upper redistribution structure 500 may include upper redistribution insulating layers 510 that are mutually stacked in the vertical direction (Z-axis direction). The upper redistribution insulating layers 510 may be formed of and/or include, for example, a photo imageable dielectric (PID) or photosensitive polyimide (PSPI).

The upper redistribution patterns 530 may be provided in the upper redistribution insulating layers 510. The upper redistribution patterns 530 may penetrate the upper redistribution insulating layers 510 from the upper surface of the upper redistribution structure 500 to a lower surface of the upper redistribution structure 500. Therefore, the upper redistribution patterns 530 may serve as electrical connection passages penetrating the upper and lower surfaces of the upper redistribution structure 500. The first semiconductor chip 200 and the second semiconductor chip 300 arranged on the upper surface of the upper redistribution structure 500 may be electrically connected through the upper redistribution patterns 530 to the bridge chip 400 and the conductive pillars 650 arranged on the lower surface of the upper redistribution structure 500. The upper redistribution patterns 530 may be formed of and/or include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Bc), gallium (Ga), or ruthenium (Ru), or an alloy thereof. In some embodiments, the upper redistribution patterns 530 may be formed by depositing a metal or a metal alloy on a seed layer including copper (Cu), titanium (Ti), titanium nitride, or titanium tungsten.

The upper redistribution patterns 530 may include upper redistribution line patterns 533 and upper redistribution via patterns 531. The upper redistribution patterns 530 may have a multilayer structure in which the upper redistribution line patterns 533 and the upper redistribution via patterns 531 are alternately stacked (e.g., alternate between upper redistribution line patterns and upper redistribution via patterns 531 in a vertical direction).

The upper redistribution line patterns 533 may have an elongated shape extending in the horizontal direction along at least one of upper and lower surfaces of each of the upper redistribution insulating layers 510. The upper redistribution via patterns 531 may have an elongated shape extending through the upper redistribution insulating layers 510 in the vertical direction (Z-axis direction). The upper redistribution via patterns 531 may electrically connect the upper redistribution line patterns 533 disposed at different levels in the vertical direction (Z-axis direction) to each other.

In some embodiments, at least some of the upper redistribution line patterns 533 may be formed together with some of the upper redistribution via patterns 531 to form one-piece bodies.

In some embodiments, the upper redistribution via patterns 531 may each have a tapered shape such that the horizontal width of each of the upper redistribution via patterns 531 may increase as the level of the upper redistribution via pattern 531 decreases in the vertical direction (Z-axis direction). For example, the horizontal widths of the upper redistribution via patterns 531 may increase as the distance from the first semiconductor chip 200 or the second semiconductor chip 300 increases in the vertical direction (negative Z-axis direction). In the same sense, the horizontal widths of the upper redistribution via patterns 531 may increase as the distance from the first substrate 100 increases. When the upper redistribution structure 500 is formed after the first semiconductor chip 200 and the second semiconductor chip 300 are formed through a chip-first process, the upper redistribution via patterns 531 may each have a tapered shape as described above such that the horizontal width of each of the upper redistribution via patterns 531 may increase as the level of the upper redistribution via pattern 531 decreases in the vertical direction (negative Z-axis direction).

The upper redistribution patterns 530 may be electrically connected to the first semiconductor chip 200 and the second semiconductor chip 300. For example, an upper redistribution via pattern 531 of the upper redistribution via patterns 531 may be electrically connected to a respective semiconductor chip pad of a plurality of semiconductor chip pads formed on the lower surfaces of the first semiconductor chip 200 and the second semiconductor chip 300. According to some embodiments, the semiconductor chip pads formed on the first semiconductor chip 200 and the second semiconductor chip 300 may each be directly connected to a respective upper redistribution via pattern 531 of the upper redistribution via patterns 531. The semiconductor chip pads may each be electrically connected to a respective upper redistribution via pattern 531 without connection bumps such as solder balls therebetween.

The bridge chip 400 may be under the upper redistribution structure 500. The bridge chip 400 may be configured to connect different types of semiconductor chips and may include a process chip, a logic chip, a memory chip, or the like. For example, the bridge chip 400 may serve as a bridge electrically connecting a logic chip and a memory chip to each other and may have a pitch corresponding to a fine pitch of each of the logic chip and the memory chip.

According to embodiments, the bridge chip 400 may be electrically connected to the upper redistribution patterns 530. The bridge chip 400 may include a bridge chip pad 410 and wiring patterns 420. The bridge chip pad 410 may be disposed on the upper surface of the bridge chip 400. The upper surface of the bridge chip 400 may face the upper redistribution structure 500. The bridge chip 400 may include a plurality of bridge chip pads 410 that are spaced apart from each other in the horizontal direction. Each bridge chip pad 410 of the plurality of bridge chip pads 410 may be electrically connected to a respective wiring pattern 420 of the wiring patterns 420.

According to embodiments, the bridge chip pads 410 may each include a plurality of layers. For example, the bridge chip pads 410 may each be formed of and/or include a copper layer including copper (Cu), a nickel layer including nickel (Ni), and a silver layer including silver (Ag) that are sequentially stacked in the vertical direction (Z-axis direction).

The wiring patterns 420 may be formed in the bridge chip 400, and each of the wiring patterns 420 may electrically connect different bridge chip pads 410 to each other. According to some embodiments, the wiring patterns 420 may include a bridge circuit. The bridge circuit may have a pitch corresponding to a fine pitch of pads formed on each of the different semiconductor chips and may serve as a bridge electrically connecting the semiconductor chips to each other.

For example, the first semiconductor chip 200 may be electrically connected to ends of the wiring patterns 420 through upper redistribution patterns 530 electrically connected to the lower left side of the first semiconductor chip 200, connection bumps 450 electrically connected to the upper redistribution patterns 530, and bridge chip pads 410 electrically connected to the connection bumps 450. In addition, the second semiconductor chip 300 may be electrically connected to the other ends of the wiring patterns 420 through upper redistribution patterns 530 electrically connected to the lower right side of the second semiconductor chip 300, connection bumps 450 electrically connected to the upper redistribution patterns 530, and bridge chip pads 410 electrically connected to the connection bumps 450. Because both ends of each of the wiring patterns 420 are electrically connected to each other, the first semiconductor chip 200 and the second semiconductor chip 300 may be electrically connected to each other.

According to embodiments, some of the bridge chip pads 410 may be electrically connected to the first semiconductor chip 200 through the connection bumps 450 and the upper redistribution patterns 530, and the rest of the bridge chip pads 410 may be electrically connected to the second semiconductor chip 300 through the connection bumps 450 and the upper redistribution patterns 530.

The first insulating layer 600 may be provided below the upper redistribution structure 500 and may surround the bridge chip 400. According to embodiments, the first insulating layer 600 may be formed of and/or include a dielectric film such as Ajinomoto Build-up Film (ABF)®. The first insulating layer 600 may serve as a mold that fixes the bridge chip 400.

The conductive pillars 650 may be spaced apart from the bridge chip 400 in horizontal directions. According to some embodiments, a plurality of conductive pillars 650 may be provided. The conductive pillars 650 may electrically connect the upper redistribution patterns 530 and the lower redistribution structure 700 to each other. For example, a conductive pillar 650 may be vertical connection conductors for electrically connecting a respective upper redistribution structure 500 and a respective lower redistribution structure 700 to each other. According to embodiments, the length of the conductive pillars 650 may range from 60 μm to 100 μm in the vertical direction (Z-axis direction).

According to embodiments, the conductive pillars 650 may each have a tapered shape such that the horizontal width of each of the conductive pillars 650 may increase as the level of the conductive pillar 650 decreases in the vertical direction (Z-axis direction). For example, the conductive pillars 650 may be shaped such that the horizontal width of each of the conductive pillars 650 may increase as the distance from the upper redistribution structure 500 increases. The conductive pillars 650 may be shaped such that the horizontal cross-sectional area of each of the conductive pillars 650 may increase as the level of the conductive pillar 650 decreases in the vertical direction (negative Z-axis direction).

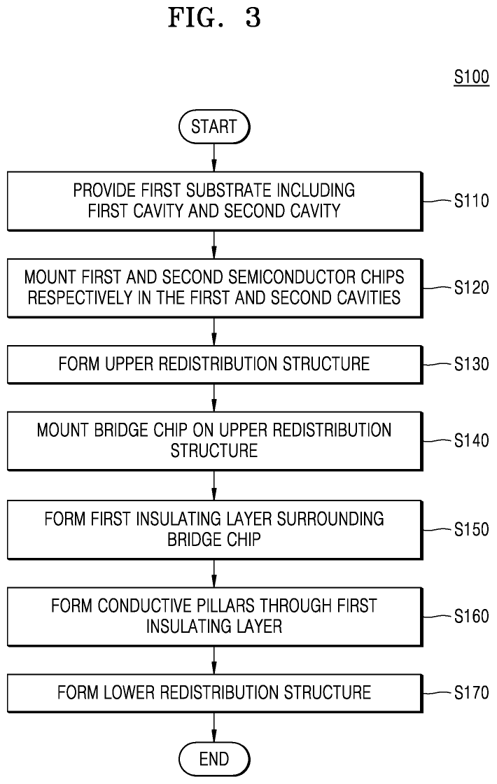

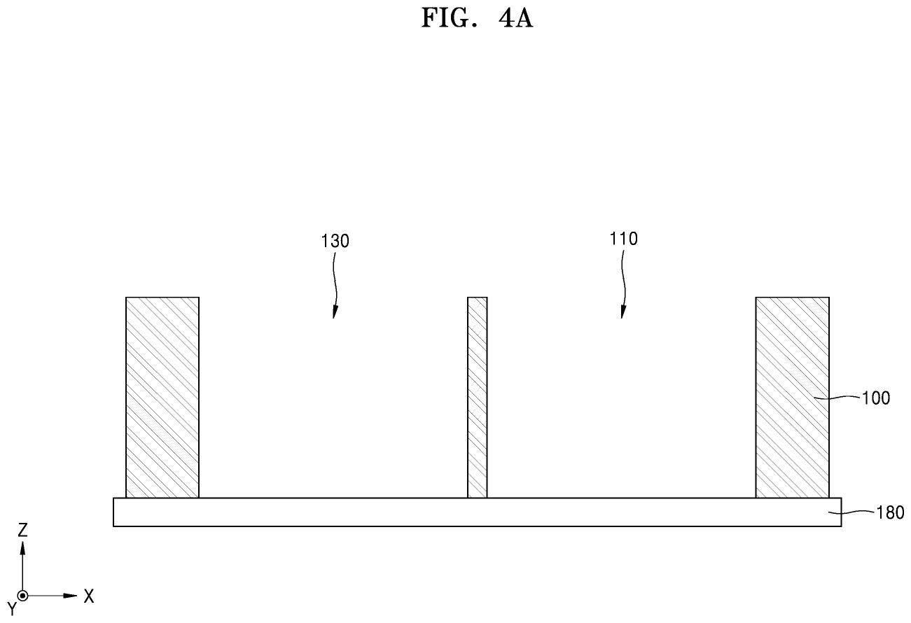

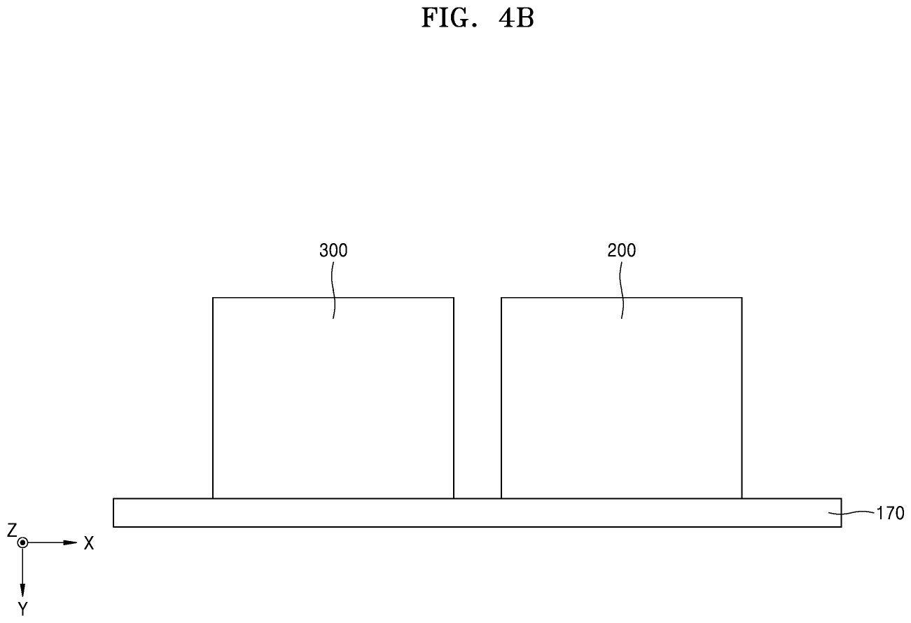

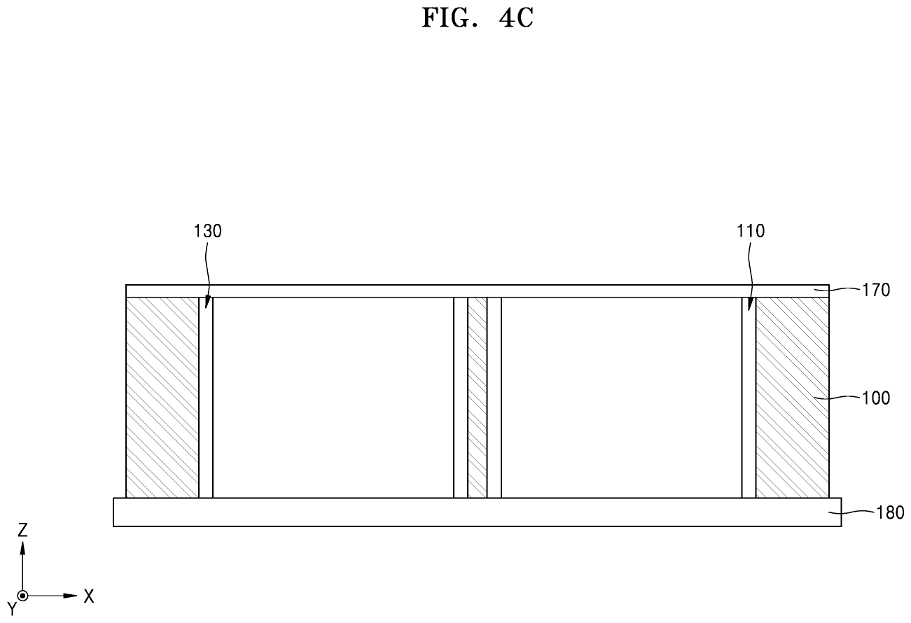

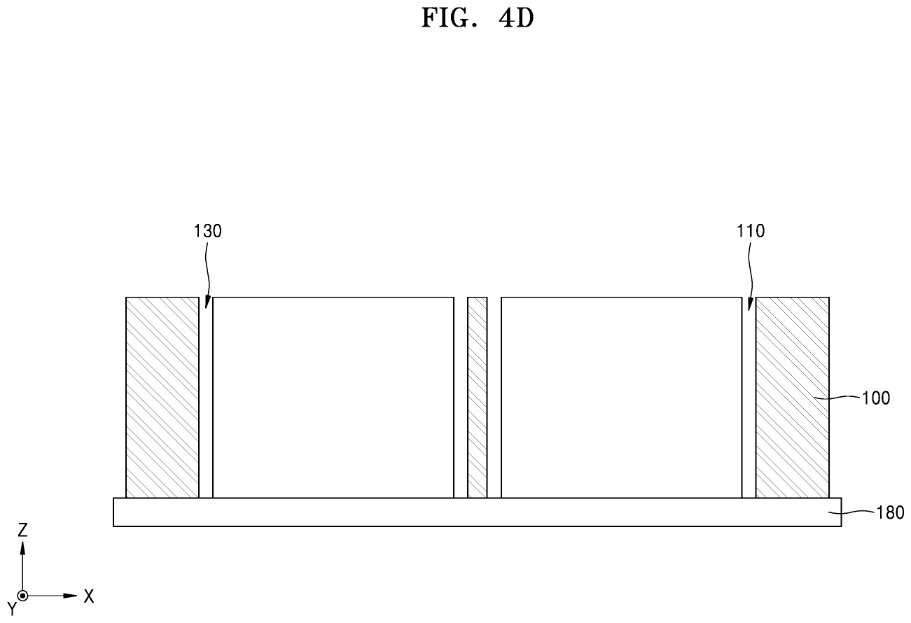

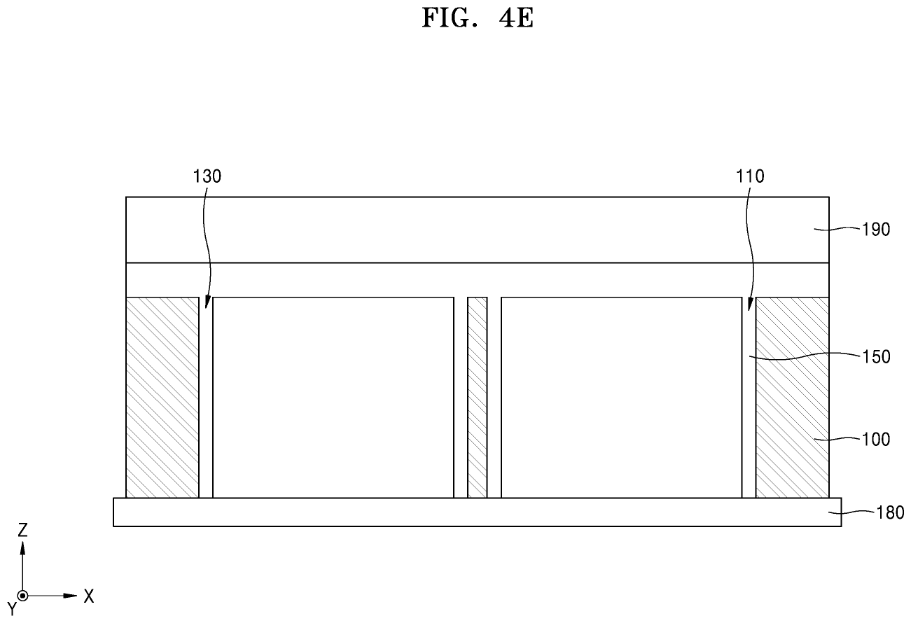

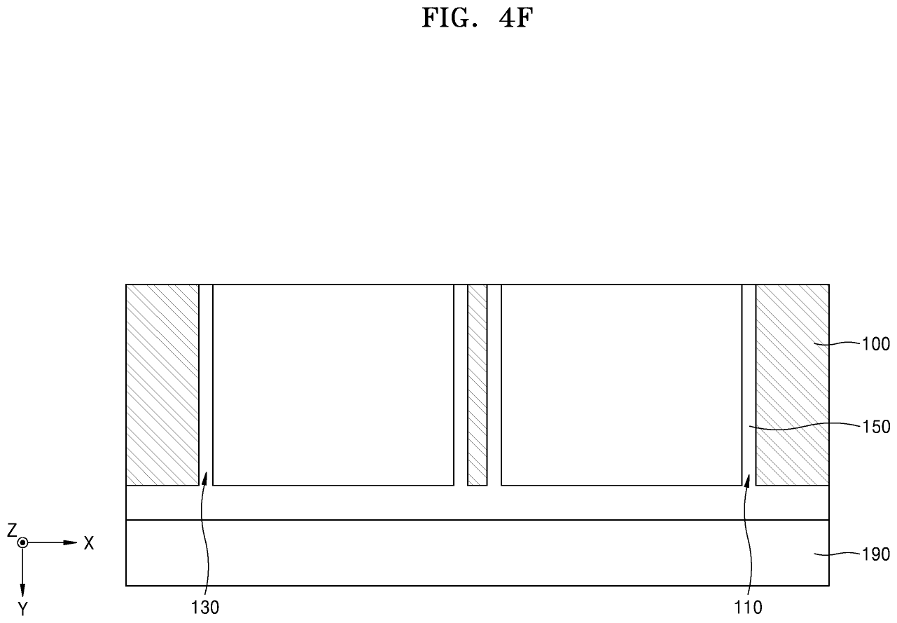

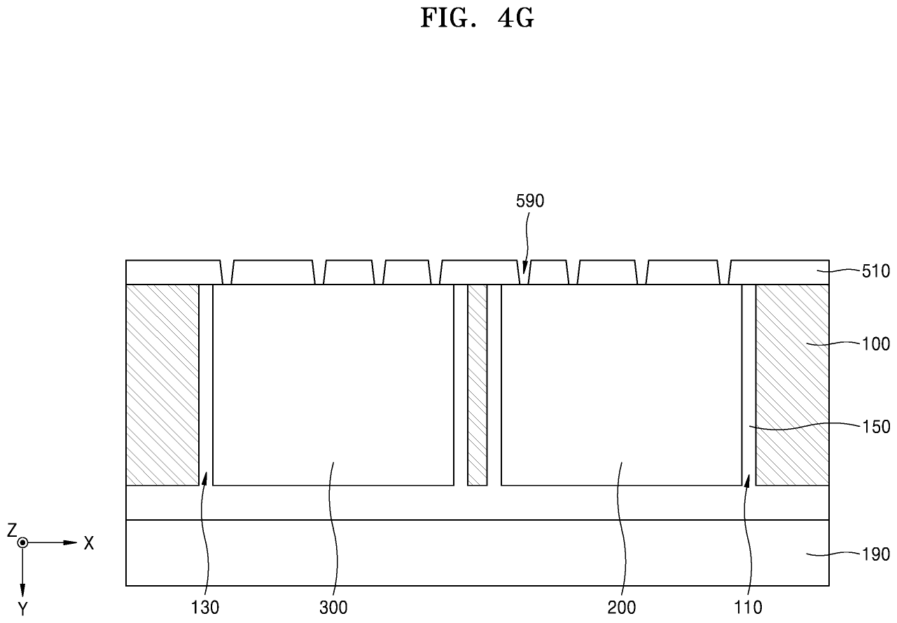

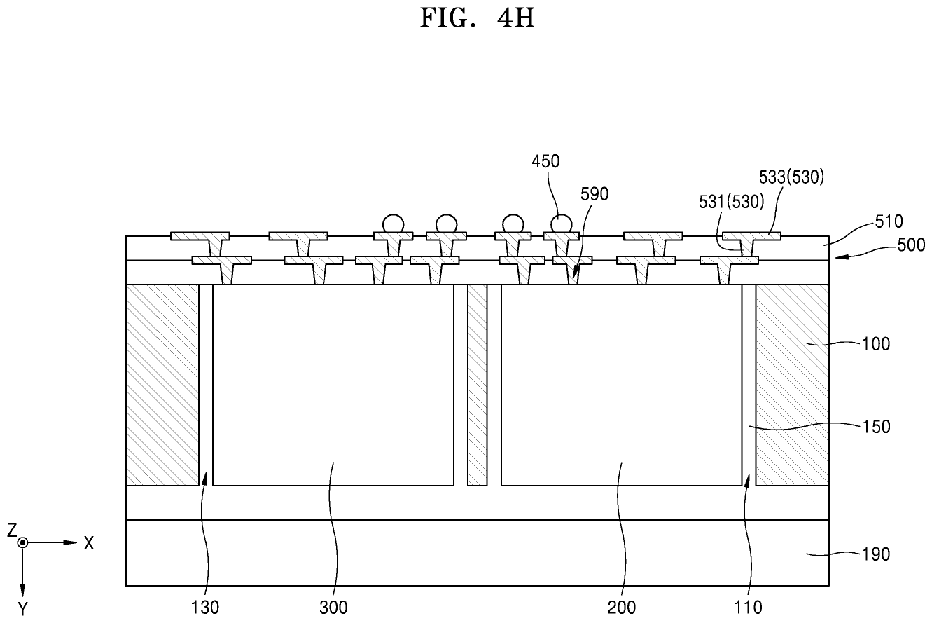

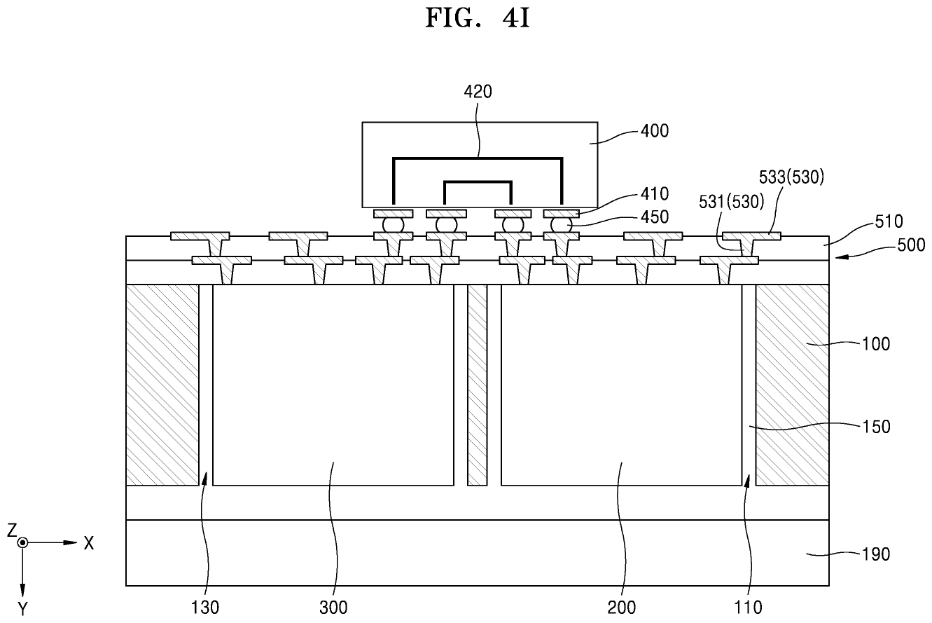

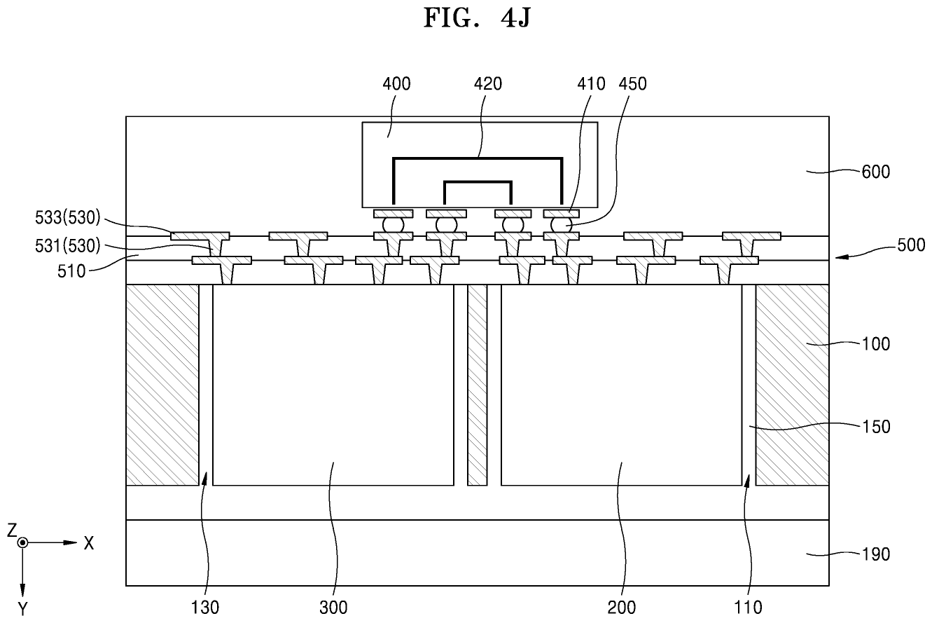

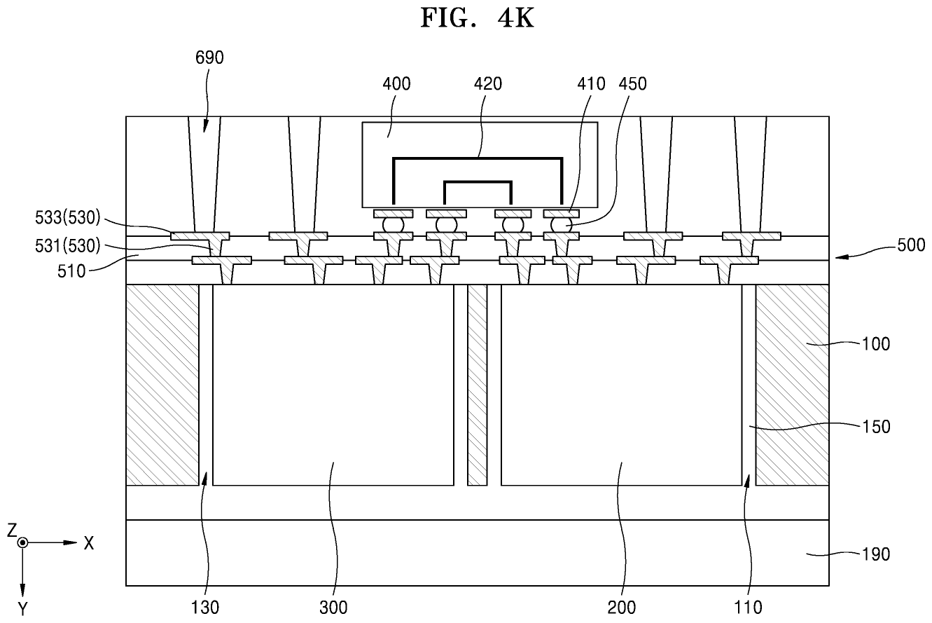

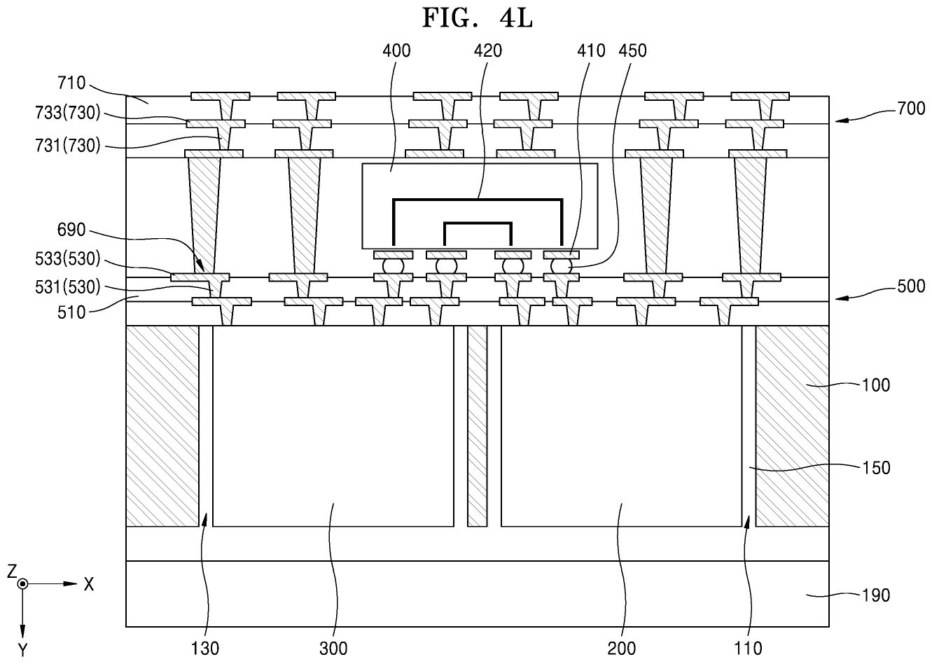

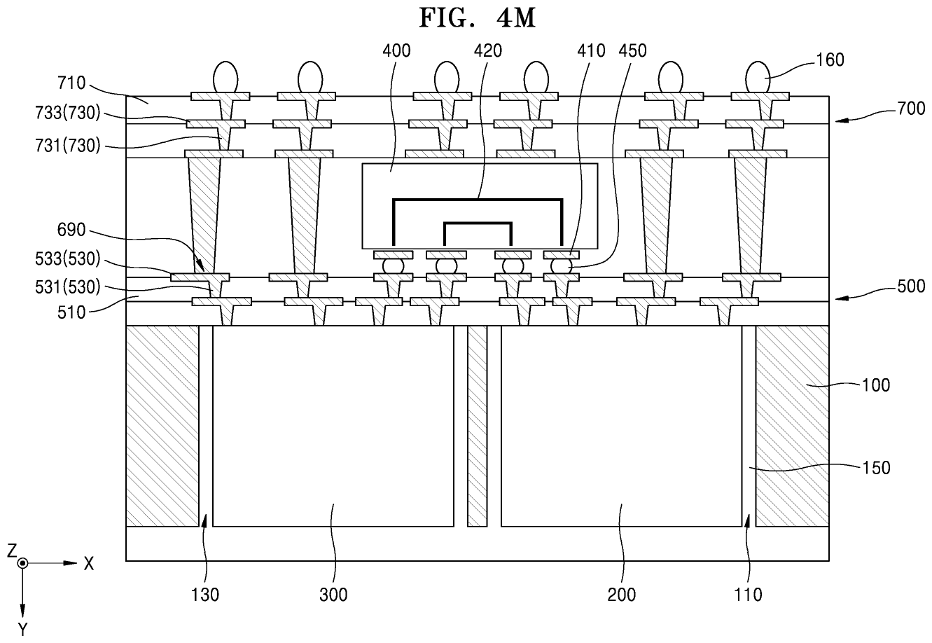

The conductive pillars 650 may penetrate the first insulating layer 600 in the vertical direction (Z-axis direction) and may pass completely through the first insulating layer 600. According to some embodiments, the conductive pillars 650 may be formed by filling openings formed in the first insulating layer 600. The conductive pillars 650 may be formed of and/or include, for example, copper (Cu). A method of forming the conductive pillars 650 is described with reference to FIGS. 3, 4J, and 4K.

The lower redistribution structure 700 may include lower redistribution insulating layers 710 and lower redistribution patterns 730. The lower redistribution patterns 730 may include lower redistribution via patterns 731 and lower redistribution line patterns 733. The structure of the lower redistribution insulating layers 710 and the lower redistribution patterns 730 may be the same as or similar to the upper redistribution insulating layers 510 and the upper redistribution patterns 530 described above, and thus, redundant descriptions thereof may be omitted.

External connection bumps 160 may be provided on the lower surface of the lower redistribution structure 700. The external connection bumps 160 may be electrically connected to an external device, for example, a motherboard. The external connection bumps 160 may be electrically connected to the lower redistribution patterns 730. The external connection bumps 160 may electrically and physically connect the semiconductor package 10 and the external device to each other. The lower redistribution patterns 730 may be electrically connected to the external device through the external connection bumps 160. The external connection bumps 160 may be formed of and/or include a conductive material. For example, the external connection bumps 160 may be formed of and/or include at least one selected from the group consisting of solder, tin (Sn), silver (Ag), copper (Cu), and aluminum (Al).

In some semiconductor packages, a first semiconductor chip and a second semiconductor chip may be surrounded by a molding member, and a bridge chip 400 may also be surrounded by another molding member. For example, in some semiconductor packages, when the semiconductor package is formed, a process of forming a molding member may be performed twice (e.g., once to surround the semiconductor chips and once to surround the bridge chip). During the molding processes, the density of the molding members may not be uniform. Thus, some semiconductor packages may have warpage, and it may be difficult to control the lengths of the molding members in the vertical direction (Z-axis direction).

According to embodiments of semiconductor packages 10 formed according to the present disclosure, the first semiconductor chip 200 and the second semiconductor chip 300 are surrounded by the first substrate 100, and the bridge chip 400 is surrounded by the insulating layer 600. The first substrate 100, which includes the first cavity 110 and the second cavity 130, serves as a molding member, and the first insulating layer 600 serves as a molding member. Thus, there may be a decrease in warpage caused by molding members having a non-uniform density during a molding process. In addition, because vertical length (Z-axis length) control is easier when forming the first substrate 100 and the first insulating layer 600 as compared to a molding member, the vertical length (Z-axis length) of the semiconductor package 10 may be more easily controlled than in other semiconductor packages.

In addition, as described below with reference to FIGS. 3, 4J, and 4K, the conductive pillars 650 of embodiments of the semiconductor package 10 according to the present disclosure may be formed by forming the first insulating layer 600, forming second holes 690 (refer to FIG. 4K) in the first insulating layer 600, and filling the second holes 690 with conductive material to form the conductive pillars 650. Therefore, compared to a method of the related art in which the bridge chip 400 is formed after the conductive pillars 650 are formed, the amount of photoresist that remains on the semiconductor package 10 may be reduced and the length of the conductive pillars 650 may be easily increased in the vertical direction (Z-axis direction).

Other semiconductor package manufacturing processes may use a method to form conductive pillars in which conductive pillars are formed before a bridge chip is formed. In such a method a film such as a photoresist film may be formed on the semiconductor package, the conductive pillars may be filled in patterns formed by exposing the film to remove selective portions of the film, and then the film may be removed. However, when the film is removed, film residue such as photoresist may remain on the semiconductor package, and thus, the quality of the semiconductor package may deteriorate.

In embodiments according to the present disclosure, when the semiconductor package 10 is manufactured, the second holes 690 (refer to FIG. 4K) are directly formed in the first insulating layer 600 and the conductive pillars 650 are filled in the second holes 690. The first insulating layer 600 remains after forming the conductive pillars 650 and is not removed. Thus, since the first insulating layer 600 is not removed, the amount of residue may be reduced. In addition, because the first insulating layer 600 is not removed but is used to fix the conductive pillars 650, the vertical length (Z-axis length) of the conductive pillars 650 may be easily increased.

FIG. 2 is a cross-sectional view schematically illustrating an example of the first semiconductor chip 200 according to an embodiment. Here, components previously described with reference to FIG. 1 may be described in brief or not at all in reference to FIG. 2, and components not previously described in references to FIG. 1 or that differ from the previous description may be described in further detail.

Referring to FIG. 2, the first semiconductor chip 200 may be a chip assembly that includes a plurality of semiconductor chips 210 and a base semiconductor chip 201 that are vertically stacked on the upper redistribution structure 500. According to some embodiments, the base semiconductor chip 201 and the semiconductor chips 210 may be HBM DRAM chips used in an HBM package.

According to some embodiments, the base semiconductor chip 201 and the semiconductor chips 210 may each include penetration electrodes 220 therein (e.g., an electrode that passes from a top surface to a bottom surface of a semiconductor chip). In addition, a top semiconductor chip 211, which is the uppermost semiconductor chip among the semiconductor chips 210, may not include penetration electrodes.

According to some embodiments, the base semiconductor chip 201 may include logic elements. For example, the base semiconductor chip 201 may be a logic chip. The base semiconductor chip 201 may be disposed under the semiconductor chips 210 to integrate signals of the semiconductor chips 210 and transmit the integrated signals externally. In addition, the base semiconductor chip 201 may transmit signals and power from an external source to the semiconductor chips 210. Therefore, the base semiconductor chip 201 may be referred to as a buffer chip or a control chip. In addition, the semiconductor chips 210 may include a plurality of memory devices, for example, DRAM devices. The semiconductor chips 210 may be referred to as memory chips or core chips.

The semiconductor chips 210 may be stacked on the base semiconductor chip 201 by a pad-to-pad bonding method, a bonding method using a bonding member, or a bonding method using an anisotropic conductive film (ACF). According to some embodiments, each of the semiconductor chips 210 may be mounted on a semiconductor chip such as the base semiconductor chip 201 or a lower semiconductor chip 210 by a flip chip method using first bumps 240. According to embodiments, the first bumps 240 may include micro-bumps.

According to embodiments, underfill material layers 260 surrounding the first bumps 240 may be provided between the base semiconductor chip 201 and the semiconductor chips 210. For example, the underfill material layers 260 may be formed by a capillary underfill method using an epoxy resin.

The penetration electrodes 220 may penetrate the base semiconductor chip 201 and the semiconductor chips 210 in the vertical direction (Z-axis direction). The penetration electrodes 220 may each have a shape extending in the vertical direction (Z-axis direction). FIG. 2 illustrates that the penetration electrodes 220 are shaped such that the width of each of the penetration electrodes 220 may decrease as the level of the penetration electrode 220 decreases in the vertical direction (negative Z-axis direction). However, the penetration electrodes 220 of the embodiments are not limited thereto. For example, the width of each of the penetration electrodes 220 may decrease or increase as the level of the penetration electrode 220 increases in the vertical direction. For example, the penetration electrodes 220 may have a tapered shape such that the horizontal width of each of the penetration electrodes 220 may vary according to the level of the penetration electrode 220 in the vertical direction. At least portions of the penetration electrodes 220 may have a columnar shape. The penetration electrodes 220 may include through-silicon vias (TSVs).

The film 150 may fill a gap between the base semiconductor chip 201, the semiconductor chips 210, and the first substrate 100. According to embodiments, the film 150 may cover lateral surfaces of the base semiconductor chip 201 and the semiconductor chips 210. In some embodiments, the film 150 may cover the lateral surfaces of the base semiconductor chip 201 and the semiconductor chips 210 and the upper surface of the top semiconductor chip 211.

The base semiconductor chip 201 may be electrically connected to the upper redistribution patterns 530 provided on the lower surface of the base semiconductor chip 201. For example, the base semiconductor chip 201 may be electrically connected to the upper redistribution via patterns 531.

According to embodiments, the base semiconductor chip 201 may be electrically connected to the upper redistribution patterns 530 without connection bumps such as solder balls therebetween.

FIG. 3 is a flowchart schematically illustrating an example of a semiconductor package manufacturing method to an embodiment. FIGS. 4A to 4M are cross-sectional views illustrating an example of a semiconductor package manufacturing method according to embodiments. Hereinafter, a method of manufacturing the semiconductor package 10 shown in FIG. 1, and characteristics thereof are described with reference to FIGS. 3 and 4A to 4M. In addition, the same reference numerals as those in FIG. 1 denote the same elements, and repeated descriptions thereof may be omitted.

Referring to FIG. 3, the semiconductor package manufacturing method S100 may include: providing a first substrate 100 having a first cavity 110 and a second cavity 130 (operation S110); mounting a first semiconductor chip 200 and a second semiconductor chip 300 respectively in the first cavity 110 and the second cavity 130 (operation S120); forming an upper redistribution structure 500 (operation S130); mounting a bridge chip 400 on the upper redistribution structure 500 (operation S140); forming a first insulating layer 600 surrounding the bridge chip 400 (operation S150); forming conductive pillars 650 through the first insulating layer 600 (operation S160); and forming a lower redistribution structure 700 (operation S170).

Referring to FIGS. 3 and 4A, an example of operation S110 including providing the first substrate 100 having the first cavity 110 and the second cavity 130 is demonstrated. The first substrate 100 in which the first cavity 110 and the second cavity 130 are formed may be provided on a first carrier substrate 180. For example, the first carrier substrate 180 may be formed of and/or include a polymer. The first substrate 100 may be provided in a state in which the first substrate 100 is attached to the first carrier substrate 180.

Referring to FIGS. 3 and 4B to 4C, an example of operation S120 including mounting the first semiconductor chip 200 and the second semiconductor chip 300 respectively in the first cavity 110 and the second cavity 130 is demonstrated. The first semiconductor chip 200 and the second semiconductor chip 300 may be provided in a state in which the first semiconductor chip 200 and the second semiconductor chip 300 are attached to a film tape 170, and in this state, the first semiconductor chip 200 and the second semiconductor chip 300 may be mounted respectively in the first cavity 110 and the second cavity 130 of the first substrate 100. According to some embodiments, the film tape 170 may include an adhesive tape. In the example of FIGS. 4B and 4C, the first semiconductor chip 200 and the second semiconductor chip 300 are shown inverted in FIG. 4B and are turned over in FIG. 4C so that lower surfaces of the first semiconductor chip 200 and the second semiconductor chip 300 may be in contact with the first carrier substrate 180, and upper surfaces of the first semiconductor chip 200 and the second semiconductor chip 300 may be in contact with the film tape 170.

Referring to FIGS. 4D and 4E, the film tape 170 attached to the upper surfaces of the first semiconductor chip 200 and the second semiconductor chip 300 may be removed. A film 150 may be applied to the first cavity 110 and the second cavity 130 through the upper surface of the first substrate 100 from which the film tape 170 is removed. The film 150 may be formed while filling a portion of the first cavity 110 that is not filled with the first semiconductor chip 200 and a portion of the second cavity 130 that is not filled with the second semiconductor chip 300.

According to some embodiments, the film 150 may be formed to cover the upper surfaces of the first semiconductor chip 200 and the second semiconductor chip 300. After the film 150 is formed, a second carrier substrate 190 may be attached to the upper surface of the film 150.

Referring to FIG. 4F, the second carrier substrate 190 may be turned over such that the lower surfaces of the first semiconductor chip 200 and the second semiconductor chip 300 may face upward. However, for consistency of description, spatial relative terms such as “upper surface,” “lower surface,” “above,” and “below” are used based on FIG. 4E.

Referring to FIGS. 3, 4G, and 4H, an example of operation S130 of forming the upper redistribution structure 500 is demonstrated. An upper redistribution insulating layer 510 may be formed on the lower surfaces of the first semiconductor chip 200 and the second semiconductor chip 300 to cover the lower surfaces of the first semiconductor chip 200 and the second semiconductor chip 300. According to embodiments, after the upper redistribution insulating layer 510 is formed, first holes 590 may be formed through the upper redistribution insulating layer 510 in the vertical direction (Z-axis direction). The first holes 590 may expose semiconductor chip pads formed on the lower surfaces of the first semiconductor chip 200 and the second semiconductor chip 300. The first holes 590 may be formed by patterning the upper redistribution insulating layer 510, and the patterning may be performed through an exposure process and a development process.

The first holes 590 may be shaped such that the horizontal width of each of the first holes 590 may increase in the vertical direction (Z-axis direction) away from the first substrate 100. Next, the first holes 590 may be filled with upper redistribution via patterns 531. The upper redistribution via patterns 531 may be formed while filling the first holes 590 and may be electrically connected to the semiconductor chip pads formed on the lower surfaces of the first semiconductor chip 200 and the second semiconductor chip 300.

Thereafter, upper redistribution line patterns 533 may be formed on the upper redistribution via patterns 531. However, embodiments are not limited thereto, and in some embodiments, the upper redistribution line patterns 533 may be formed simultaneously with the upper redistribution via patterns 531.

After the upper redistribution line patterns 533 are formed, another upper redistribution insulating layer 510 may be formed and upper redistribution via patterns 531 and upper redistribution line patterns 533 may be repeatedly formed.

Connection bumps 450 electrically connected to upper redistribution patterns 530 may be formed on the lowermost surface of the upper redistribution structure 500.

Referring to FIGS. 3 and 4I, an example of operation S140 of mounting the bridge chip 400 on the upper redistribution structure 500 is demonstrated. The bridge chip 400 may be mounted on the upper redistribution structure 500 such that bridge chip pads 410 formed on the bridge chip 400 may be electrically connected to the connection bumps 450.

Thereafter, referring to FIGS. 3 and 4J which demonstrate an example of operation S150, operation S150 is performed to form the first insulating layer 600 surrounding the bridge chip 400. The first insulating layer 600 may be formed of and/or include, for example, a dielectric film such as ABF. The first insulating layer 600 may be positioned on the lower surface of the upper redistribution structure 500 and may surround the bridge chip 400.

Referring to FIGS. 3 and 4K to 4M which demonstrate examples of operations S160 and S170, operation S160 of forming the conductive pillars 650 through the first insulating layer 600 is performed, and operation S170 of forming the lower redistribution structure 700 is performed.

After the first insulating layer 600 is formed, second holes 690 may be formed through the first insulating layer 600 in the vertical direction (Z-axis direction). The second holes 690 may extend in the vertical direction from the upper surface of the first insulating layer 600 to the lower surface of the first insulating layer 600. The second holes 690 may be shaped such that the horizontal width of each other second holes 690 may increase in a direction away from the upper redistribution structure 500.

After the second holes 690 are formed, the conductive pillars 650 filling the second holes 690 are formed. The conductive pillars 650 may be formed by filling the second holes 690 with, for example, copper. The second holes 690 may be filled with copper through an electroplating process or the like. According to embodiments, the first insulating layer 600 may not be removed through an additional process after the conductive pillars 650 are formed, and the conductive pillars 650 and the bridge chip 400 may be fixed by the first insulating layer 600.

After the conductive pillars 650 are formed, the lower redistribution structure 700 may be formed. In this case, the second carrier substrate 190 attached to the film 150 may be removed. The lower redistribution structure 700 is formed by a method which may be the same as or similar to the method of forming the upper redistribution structure 500, and thus, a description of the method is omitted.

Lower redistribution patterns 730 included in the lower redistribution structure 700 may be electrically connected to the conductive pillars 650. In addition, the lower redistribution patterns 730 may be electrically connected to external connection bumps 160 formed on the lower surface of the lower redistribution structure 700.

While the disclosure has been particularly shown and described with reference to embodiments thereof, it will be understood that various changes in form and details may be made therein without departing from the spirit and scope of the following claims.

What is claimed is:

1. A semiconductor package comprising:
an upper redistribution structure comprising an upper redistribution insulating layer and upper redistribution patterns in the upper redistribution insulating layer;
a first substrate comprising an upper surface, a lower surface opposite the upper surface, a first cavity extending in a vertical direction from the upper surface to the lower surface, and a second cavity provided apart from the first cavity in a horizontal direction and extending in the vertical direction from the upper surface to the lower surface, the first substrate being on an upper surface of the upper redistribution structure;
a first semiconductor chip accommodated in the first cavity and electrically connected to a first subset of the upper redistribution patterns;
a second semiconductor chip accommodated in the second cavity and electrically connected to a second subset of the upper redistribution patterns;
a bridge chip below the upper redistribution structure; and
a first insulating layer surrounding the bridge chip.

2. The semiconductor package of claim 1, wherein a first upper redistribution pattern of the upper redistribution patterns comprises an upper redistribution line pattern and an upper redistribution via pattern, and the upper redistribution via pattern has a horizontal width increasing in the vertical direction away from the first substrate.

3. The semiconductor package of claim 1, wherein the first substrate does not comprise a wiring pattern.

4. The semiconductor package of claim 1, further comprising a connection bump electrically connecting the bridge chip and a third subset of the upper redistribution patterns to each other.

5. The semiconductor package of claim 1, wherein the first insulating layer comprises a dielectric film.

6. The semiconductor package of claim 1, further comprising a conductive pillar vertically penetrating the first insulating layer, and the conductive pillar has a horizontal width increasing in a direction away from the upper redistribution structure.

7. The semiconductor package of claim 6, wherein the conductive pillar has a length of 60 μm to 100 μm in the vertical direction.

8. The semiconductor package of claim 1, further comprising a film filling a gap between the first substrate and the first semiconductor chip and a gap between the first substrate and the second semiconductor chip.

9. The semiconductor package of claim 1, wherein the first semiconductor chip comprises a plurality of high bandwidth memory (HBM) chips stacked in the vertical direction.

10. The semiconductor package of claim 1, further comprising: a lower redistribution structure below the first insulating layer, a conductive pillar electrically connecting the lower redistribution structure and the upper redistribution structure to each other, and an external connection bump provided below the lower redistribution structure and electrically connecting the lower redistribution structure to an external device.

11. A semiconductor package manufacturing method comprising:
providing a first substrate having a first cavity and a second cavity;
mounting a first semiconductor chip in the first cavity and a second semiconductor chip in the second cavity;
forming an upper redistribution structure comprising upper redistribution patterns electrically connected to each of the first semiconductor chip and the second semiconductor chip;
mounting a bridge chip such that the bridge chip is electrically connected to the upper redistribution structure;
forming a first insulating layer surrounding the bridge chip;
forming a conductive pillar penetrating the first insulating layer; and
forming a lower redistribution structure comprising a lower redistribution pattern electrically connected to the conductive pillar.

12. The semiconductor package manufacturing method of claim 11, wherein the first insulating layer comprises a dielectric film.

13. The semiconductor package manufacturing method of claim 11, wherein the mounting of the first semiconductor chip in the first cavity and the second semiconductor chip in the second cavity comprises forming a film filling a gap between the first substrate and the first semiconductor chip and a gap between the first substrate and the second semiconductor chip after mounting the first semiconductor chip and the second semiconductor chip in the first substrate.

14. The semiconductor package manufacturing method of claim 11, wherein
the lower redistribution structure is below the bridge chip,
the conductive pillar is spaced horizontally apart from the bridge chip and electrically connects the upper redistribution structure and the lower redistribution structure to each other, and
the first insulating layer surrounds the bridge chip and the conductive pillar.

15. The semiconductor package manufacturing method of claim 11, wherein the bridge chip and an upper redistribution pattern of the upper redistribution patterns are electrically connected through a connection bump.

16. The semiconductor package manufacturing method of claim 11, wherein the forming of the conductive pillar penetrating the first insulating layer comprises:
forming a second hole penetrating the first insulating layer in a vertical direction; and forming the conductive pillar by filling the second hole.

17. The semiconductor package manufacturing method of claim 16, wherein the conductive pillar has a horizontal width increasing in a direction away from the upper redistribution structure.

18. A semiconductor package comprising:
an upper redistribution structure comprising an upper redistribution insulating layer and upper redistribution patterns in the upper redistribution insulating layer;
a first substrate comprising an upper surface, a lower surface opposite the upper surface, a first cavity extending in a vertical direction from the upper surface to the lower surface, and a second cavity provided apart from the first cavity in a horizontal direction and extending in the vertical direction from the upper surface to the lower surface, the first substrate being on an upper surface of the upper redistribution structure;
a first semiconductor chip accommodated in the first cavity and electrically connected to a first subset of the upper redistribution patterns;
a second semiconductor chip accommodated in the second cavity and electrically connected to a second subset of the upper redistribution patterns;
a film filling a gap between the first substrate and the first semiconductor chip and a gap between the first substrate and the second semiconductor chip;
a bridge chip below the upper redistribution structure;
a first insulating layer surrounding the bridge chip;
a conductive pillar penetrating the first insulating layer in the vertical direction; and
a lower redistribution structure provided below the first insulating layer and comprising a lower redistribution pattern electrically connected to the conductive pillar,
wherein the upper redistribution patterns comprise upper redistribution line patterns and an upper redistribution via pattern that has a horizontal width increasing in the vertical direction away from the first substrate,
the conductive pillar has a horizontal width decreasing in the vertical direction away from the upper redistribution structure, and
the first insulating layer comprises a dielectric film.

19. The semiconductor package of claim 18, wherein the conductive pillar has a length of 60 μm to 100 μm in the vertical direction.

20. The semiconductor package of claim 18, wherein the first substrate does not comprise a wiring pattern.
